(19) United States
(12) Patent Application Publication
(10) Pub. No.: US 2004/0124516 A1
(43) Pub. Date: Jul. 1, 2004

(54) Circuit device, circuit module, and method for manufacturing circuit device

(76) Inventors: Takeshi Nakamura, Gunma (JP); Yusuke Igarashi, Gunma (JP); Noriaki Sakamoto, Gunma (JP)

Correspondence Address: FISH & RICHARDSON P.C., 45 ROCKEFELLER PLAZA, SUITE 2800, NEW YORK, NY, 10111, US

(21) Appl. No.: 10/701,915

(22) Filed: Nov. 5, 2003

(30) Foreign Application Priority Data
Nov. 6, 2002 (JP) P. 2002-322110

(51) Int. Cl. H01L 23/02

(52) U.S. Cl. 257/685

(57) ABSTRACT

A second conductive pattern 14 is provided on the upper surface of a circuit device 10. A second conductive pattern 14 is provided on the upper surface of an insulating resin 13 which seals a built-in first circuit element 12, etc., and a first conductive pattern 11 and the second conductive pattern 14 are electrically connected via connection means 15. Second circuit elements 22 are mounted on the second conductive pattern 14. Thus, circuit elements can be three-dimensionally mounted. Furthermore, since the circuit device 10 eliminates the need for a mounting substrate, a low-profile circuit device is provided.

### BACKGROUND OF THE INVENTION

1. Field of the Invention

The present invention relates to a circuit device in which a first circuit element is mounted in three-dimensional array by forming a conductive pattern on an upper surface of a resin layer and relates to a method for manufacturing the same.

2. Description of the Related Art

Conventionally, circuit devices to be set in electronic apparatuses have been required to be small in size, low-profile, and lightweight since the circuit devices are used for portable telephones, portable computers and so on. For example, a semiconductor device as a circuit device is typically a package-type semiconductor device which is conventionally sealed by normal transfer molding. This semiconductor device is mounted on a printed circuit board PS as shown in FIG. 18.

This package-type semiconductor device 61 has a semiconductor chip 62 covered with a resin layer 63, with a lead terminal 64 for external connection derived from the side of this resin layer 63. However, this package-type semiconductor device 61 had the lead terminal 64 out of the resin layer 63, and was too large in total size to meet the requirement of small size, low-profile and lightweight. Therefore, various companies have competed to develop a wide variety of structures that are reduced in size, thickness and weight. Recently, a wafer scale CSP which is as large as a chip size, called a CSP (Chip Size Package), or a CSP which is slightly larger than the chip size, has been developed.

FIG. 19 shows a CSP 66 that adopts a glass epoxy substrate 65 as a support substrate and that is slightly larger than a chip size. Herein, a transistor chip T is mounted on the glass epoxy substrate 65.

A first electrode 67, a second electrode 68, and a die pad 69 are formed on the upper surface of the glass epoxy substrate 65, and a first back electrode 70 and a second back electrode 71 are formed on the rear surface thereof. Via a through hole TH, the first electrode 67 and the first back electrode 70, as well as the second electrode 68 and the second back electrode 71, are electrically connected together. The bare transistor chip T is fixed onto the die pad 69. An emitter electrode of the transistor and the first electrode 67 are connected together through a thin metal wire 72, and a base electrode of the transistor and the second electrode 68 are connected together through the thin metal wire 72. Furthermore, a resin layer 73 is provided on the glass epoxy substrate 65 to cover the transistor chip T.

The CSP 66 adopts the glass epoxy substrate 65, which has the advantages of a simpler structure extending from the chip T to the back electrodes 70 and 71 for external connection, and a less expensive manufacturing cost than the wafer scale CSP. The CSP 66 is mounted on the printed circuit board PS, as shown in FIG. 18. The printed circuit board PS is provided with the electrodes and wiring making up an electric circuit, and has the CSP 66, the package-type semiconductor device 61, a chip resistor CR, or a chip capacitor CC, etc., electrically connected and fixed thereto. The circuit on this printed circuit board is packaged in various sets.

However, in the above-described semiconductor device such as a CSP, since the transistor chip T has no pattern on the upper surface of the resin layer 73, mounting of the semiconductor device in three-dimensional array is difficult. Accordingly, for mounting a multiple number of semiconductor devices on the printed circuit board PS, the semiconductor devices must be mounted in two-dimensional array, and this causes an increase in the size of the printed circuit board PS.

### SUMMARY OF THE INVENTION

The preferred embodiments of present invention have been made in view of such problems, and it is one of the objects of the preferred embodiment of the present invention to provide a circuit device having a three-dimensional mounting structure and a method for manufacturing the circuit device.

The circuit device of the preferred embodiments comprises:

a first conductive pattern; a first circuit element mounted on the first conductive pattern; an insulating resin for covering at least the first circuit element and the first conductive pattern;

a second conductive pattern provided on an upper surface of the insulating resin; a through hole formed in the insulating resin so that an upper surface of the first conductive pattern is partially exposed; a connection means provided on a bottom surface and a side surface of the through hole and electrically connecting the first conductive pattern with the second conductive pattern; and a second circuit element mounted on the second conductive pattern.

As such, by forming the second conductive pattern on the upper surface of the insulating resin to seal the first circuit element and mounting the second circuit elements thereon, the element can be mounted three-dimensionally, therefore, mounting density can be improved.

Furthermore, according to the preferred embodiments, a method for manufacturing a circuit device comprises the steps of: forming a first conductive pattern; fixing a first circuit device to the first conductive pattern; molding with an insulating resin so as to cover at least the first circuit element; forming through holes in the insulating resin so that the first conductive pattern is exposed; forming a second conductive pattern on an upper surface of the insulating resin and, furthermore, forming connection means on a side surface and a bottom surface of the through holes; mounting second circuit elements on the second conductive pattern; and separating into respective circuit devices by dicing the insulating resin.

As described above, by simultaneously forming the second conductive pattern to be formed on the upper surface of the insulating resin and the connection means, the conductive pattern for a three-dimensional arrangement can be formed in the least possible amount of man-hours.

According to the preferred embodiments of present invention, the following effects can be provided.

First, by providing a second conductive pattern 14 on the upper surface of the insulating resin 13 to seal the whole and mounting second circuit elements 22 on the second conductive pattern 14, three-dimensional mounting of the element becomes possible. Furthermore, since the circuit device 10 is supported by the insulating resin 13, a low profile and lightweight circuit device is realized.

Second, by providing a shield layer 14A on the upper surface of the insulating resin 13, at a part where the second conductive pattern 14 is not provided, noise from the outside can be prevented from entering inside the device.

Third, since the second conductive pattern and connection means 15 are formed of an integrated plated film, it becomes possible to form the second conductive pattern and connection means simultaneously, thus the number of the process steps can be reduced.

### DESCRIPTION OF THE DRAWINGS

FIG. 1A is a sectional view, FIG. 1B is a plan view, and FIG. 1C is a plan view showing a circuit device of the present embodiments;

FIG. 2 is a plan view showing a circuit device of the present embodiments;

FIG. 3 is a sectional view showing a circuit module of the present embodiments;

FIG. 4 is a sectional view showing a method for manufacturing a circuit device of the present embodiments;

FIG. 5 is a sectional view showing a method for manufacturing a circuit device of the present embodiments;

FIG. 6 is a sectional view showing a method for manufacturing a circuit device of the present embodiments;

FIG. 7 is a sectional view showing a method for manufacturing a circuit device of the present embodiments;

FIG. 8 is a sectional view showing a method for manufacturing a circuit device of the present embodiments;

FIG. 9 is a sectional view showing a method for manufacturing a circuit device of the present embodiments;

FIG. 10 is a sectional view showing a method for manufacturing a circuit device of the present embodiments;

FIG. 11 is a sectional view showing a method for manufacturing a circuit device of the present embodiments;

FIG. 12 is a sectional view showing a method for manufacturing a circuit device of the present embodiments;

FIG. 13 is a sectional view showing a method for manufacturing a circuit device of the present embodiments;

FIG. 14 is a sectional view showing a method for manufacturing a circuit device of the present embodiments;

FIG. 15 is a sectional view showing a method for manufacturing a circuit device of the present embodiments;

FIG. 16 is a sectional view showing a method for manufacturing a circuit device of the present embodiments;

FIG. 17 is a sectional view showing a method for manufacturing a circuit device of the present embodiments;

FIG. 18 is a sectional view showing a related circuit device;

FIG. 19 is a sectional view showing a related circuit device.

### DESCRIPTION OF THE PREFERRED EMBODIMENTS

First embodiment for describing a configuration of a circuit device 10

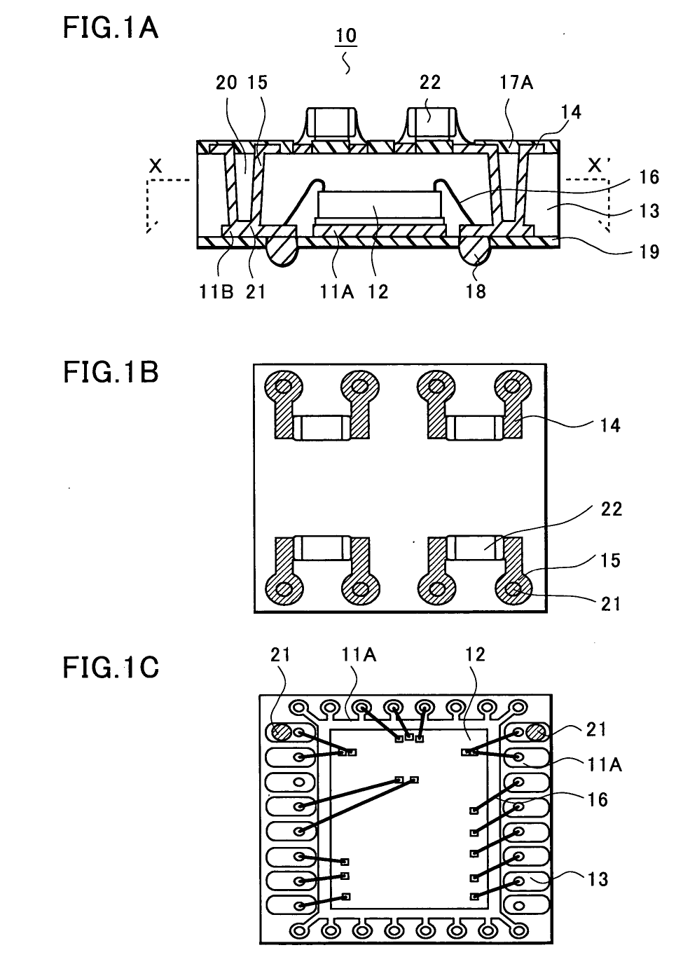

The configuration of a circuit device 10 of the preferred embodiment will be described with reference to FIG. 1. FIG. 1A is a sectional view of a circuit device 10, FIG. 1B is a top view thereof, and FIG. 1C is a plan view along a line X-X′ of FIG. 1A.

Referring to FIG. 1A through FIG. 1C, the circuit device 10 has the following configuration. Namely, the circuit device 10 comprises a first conductive pattern 11 on which a first circuit element 12 is mounted, an insulating resin 13 covering at least the first circuit element 12 and first conductive pattern, a second conductive pattern 14 provided on the upper surface of the insulating resin 13, connection means 15 for electrically connecting the first conductive pattern 11 with the second conductive pattern 14, and second circuit elements 22 mounted on the second conductive pattern 14. Respective components such as these will be described in the following. Although the above-described first conductive pattern can be formed with a monolayer or multilayer wiring structure, a description will be herein given of a monolayer wiring structure.

The first conductive pattern 11 is formed of a metal such as a copper foil and is embedded in the insulating resin 13 with its rear surface exposed. Herein, a first conductive pattern 11A forms a die pad, on which the first circuit device 12 such as a semiconductor element is mounted. A first conductive patterns 11B forms bonding pads. The first conductive pattern 11A is arranged in a central part. The first circuit element 12 is fixed on the first conductive pattern 11A via a brazing material. The rear surface of a first conductive pattern 11A exposed through the insulating resin 13 is protected by a solder resist 19. A plurality of first conductive patterns 11B are arranged at a periphery portion of the circuit device so as to surround the first conductive pattern 11A, and is connected to an electrode of the first circuit element 12 via a thin metal wire 16. In addition, on the rear surface of the first conductive pattern 11B, an external electrode 18 formed of a brazing material such as solder is formed. Furthermore, on the upper surface of the first conductive pattern 11B, an exposed portion 21 is formed, and a part of the upper surface of the first conductive pattern 11B is exposed at a through hole 20 formed in the insulating resin 13.

Herein, although the side surfaces of the first conductive pattern have been linearly drawn, these are in actuality formed in a curved manner, an anchoring effect is produced between the curved side surfaces of the first conductive pattern 11 and insulating resin 13, whereby both are firmly joined.

While exposing the rear surface of the first conductive pattern 11, the insulating resin 13 seals this ensemble. Herein, the insulating resin 13 seals the semiconductor element 13, thin metal wires 16, and first conductive pattern 11 and also has a function to support the ensemble. Accordingly, a circuit device of the preferred embodiment eliminates the support substrate. In addition, as the material for the insulating resin 13, a thermosetting resin formed by transfer molding and a thermoplastic resin formed by injection molding can be employed.

The first circuit device 12 is, for example, a semiconductor element, and herein, an IC chip is fixed on the first conductive pattern 11A face-up. In addition, the electrodes of the first circuit element 12 and the first conductive patterns 11B are electrically connected via the thin metal wires 16. Although the first circuit element 12 which is a semiconductor element is fixed face-up, this element may be fixed face-down. Moreover, as the first circuit element 12, in addition to an IC chip, an active element such as a transistor chip or a diode and a passive element such as a chip resistor or a chip capacitor can be employed. Still furthermore, a plurality of elements of these active elements and passive elements can also be arranged on the first conductive pattern 11.

A through hole 20 is formed by partial removal of the insulating resin 13, and at a bottom portion thereof, the exposed portion 21 as a part of the upper surface of the first conductive pattern 11B is exposed. On a side surface portion of this through hole 20 and the exposed portion 21, the connection means 15 formed of a metal film is formed, which has a function to electrically connect the second conductive pattern 14 formed on the upper surface of the insulating resin 13 to the first conductive pattern 11B with the exposed portion 21 formed. In addition, as for the shape of the through hole 20, a section in the plane direction is formed with a roughly circular shape and a section in the vicinity of the upper surface of the insulating resin 13 is formed greater than that in the vicinity of the exposed portion 21.

The second conductive pattern 14 is formed of a metal such as copper, and this is deposited by electrolytic plating or electroless plating on the upper surface of the insulating resin 113. These condconductive pattern 14 and first conductive pattern 11 are electrically connected by the connection means 15. In addition, referring to FIG. 1B, the second conductive pattern 14 forms a pattern on which four second circuit elements 22 are mounted.

The second circuit elements 22 are fixed to the second pattern 14 formed on the upper surface of the insulating resin 13 via a brazing material. As the second circuit elements 22, passive elements such as chip resistors or chip capacitors can be employed. Furthermore, LSI chips, transistors or the like can also be mounted as second circuit elements 22 on the second conductive pattern 14.

The connection means 15 is a metal layer formed on the side surface and bottom surface of the through hole 20, which is formed by partial removal of the insulating resin 13, and this has a function to electrically connect the first conductive pattern 11 and the second conductive pattern 14. In addition, referring to FIG. 1A, the connection means 15 can also be formed so as to be filled in the through hole 20.

The above-described second conductive pattern 14 and connection means 15 are integrally formed by plating. By plating, a uniform metal layer can be formed on the upper surface of the insulating resin 13, the side surface of the through hole 20, and the exposed portion 21 of the first conductive pattern 11B. Accordingly, by the connection means 15 formed integrally with the second conductive pattern 14, the first conductive pattern 11 and the second conductive pattern 14 are electrically securely connected.

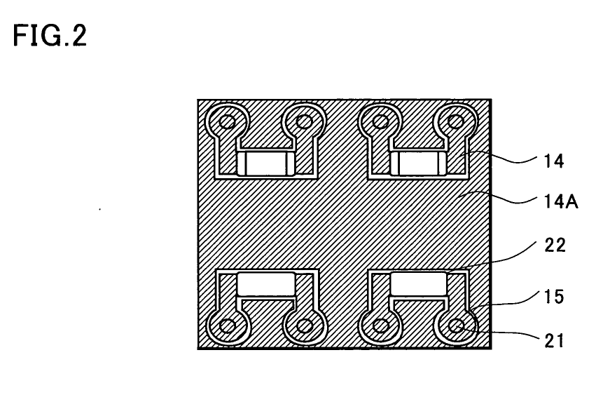

Referring to FIG. 2, a structure of the circuit device 10 when a shield layer 14A is provided on the upper surface of the insulating resin 13 will be described. Herein, the upper surface of the insulating resin 13 is provided with a second conductive pattern 14, and at a part other than the above, the upper surface of the insulating resin 13 is provided with a shield layer 14A. The shield layer 14A is formed in a manner electrically isolated from the second conductive pattern 14, and has a function to suppress electromagnetic waves from entering from the outside. In addition, the shield layer 14A is electrically connected with the first conductive pattern 11 via the connection means 15 so as to become a ground potential, whereby effects of this shield can further be improved.

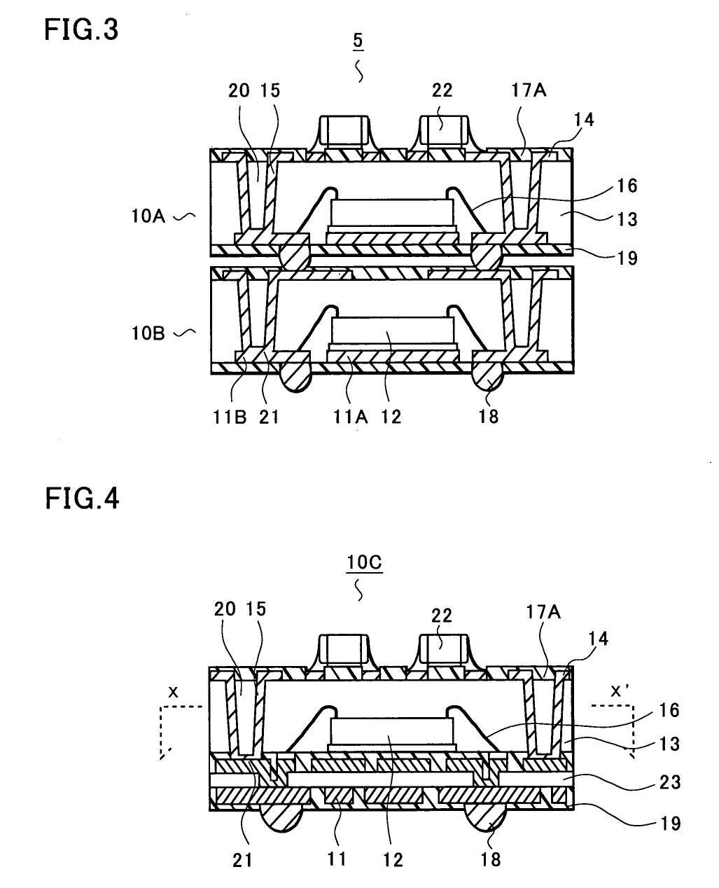

Referring to FIG. 3, a configuration of a circuit module wherein circuit devices as shown in FIG. 1 are provided in a stack structure will be described.

A circuit module 5 comprises: a first circuit device 10A having; a first conductive pattern 11 on which a first circuit element 12 is mounted, an insulating resin 13 covering at least the first circuit element 12; a second conductive pattern 14 provided on the upper surface of the insulating resin 13; connection means 15 for electrically connecting the first conductive pattern 11 with the second conductive pattern 14; external electrodes 18 provided on the rear surface of the first conductive pattern 11 and a second circuit device 10B having an identical configuration to the first circuit device, wherein the first circuit device 10A is fixed in a stack structure to an upper portion of the second circuit device 10B via the external electrodes 18 of the first circuit device 10A.

As described above, herein, the first and second circuit devices 10A and 10B are fixed in a stack structure via the external electrodes 18. Accordingly, the second conductive pattern 14 provided on the upper surface of the insulating resin 13 of the second circuit device 10B corresponds to positions of the external electrodes 18 of the first circuit device 10A.

Although, herein, the two circuit devices 10 are fixed in a stack structure, it is also possible to further stack a multiple number of circuit devices 10, whereby mounting density can further be improved.

Referring to FIG. 4, a circuit device 10C wherein the first conductive pattern 11 is formed in a multilayered manner will be described. The circuit device 10C hereinafter described has a configuration similar to that of the circuit device 10 described with reference to FIG. 1, and the first conductive pattern 11 is formed in a multilayered manner.

The first conductive pattern 11 is laminated in a multilayered manner via an interlayer insulating film 23, and the upper-layer first conductive pattern 11 is electrically connected to the first circuit element 12 via thin metal wires 16, and external electrodes 18 are formed at desirable sites of the lower-layer first conductive pattern 11. The upper first conductive pattern 11 is electrically connected to the second conductive pattern 14 via connection means 15. Herein, although the conductive pattern has a two-layer wiring structure, it is also possible to form a further multiple-layer.

An advantage of the preferred embodiment exists in that the second conductive pattern is provided on the upper surface of the insulating resin 13 covering the first circuit element 12. Thereby, as shown in FIG. 1, it becomes possible to realize a mounting structure in a three-dimensional array by fixing second circuit elements 22 on the second conductive pattern 14. Furthermore, as shown in FIG. 3, it becomes possible to mount a plurality of circuit devices 10 in a stack structure via the second conductive pattern 14. Accordingly, mounting density can be improved.

Furthermore, an advantage of the preferred embodiment exists in that the second conductive pattern 14 and the first conductive pattern 11 are electrically connected via through holes 20 provided by partial removal of the insulating resin 13. Concretely, on the side surface of the through hole 20 and the exposed portion 21 exposed from the bottom surface thereof, a connection means 15 formed of a metal film is formed. Moreover, since the connection means 15 and the second conductive pattern 14 are integrally formed by plating or the like, the first conductive pattern 11 and the second conductive pattern 14 are electrically connected. Thus, it is unnecessary to add another component to electrically connect both.

Still furthermore, an advantage of the preferred embodiment exists in that the circuit device 10 is configured without a mounting substrate. Concretely, the circuit device 10 is supported as a whole by the insulating resin 13, which seals the first conductive pattern 11 and first circuit element 12, wherein a mounting substrate as in the prior art is eliminated. Accordingly, the circuit device 10 is formed with an extremely low profile, thus mounting in three-dimensional array is made possible while an increase in the thickness of the device is suppressed.

Second embodiment for explaining a method for manufacturing a circuit device 10

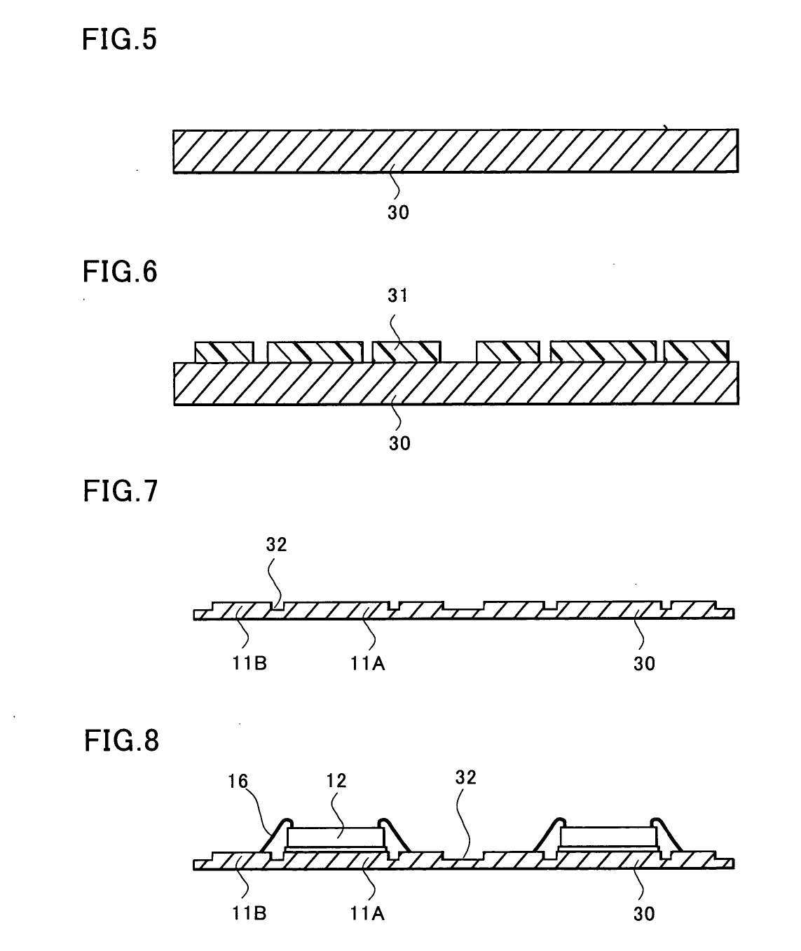

In the present embodiment, a circuit device 10 can be manufactured by the following steps. Namely, these steps are: forming a first conductive pattern 11; fixing a first circuit element 12 to the first conductive pattern 11; molding with an insulating resin 13 so as to cover at least the first circuit element; forming through holes in the insulating resin 13 so that the first conductive pattern 11 is exposed; forming a second conductive pattern 14 on a upper surface of the insulating resin 13 and, furthermore, forming connection means 15 on a side surface and a bottom surface of the through holes 20; mounting second circuit elements 22 on the second conductive pattern 14; and separating into respective circuit devices 10 by dicing the insulating resin 13. Hereinafter, the respective steps of this preferred embodiment will be described with reference to FIG. 5 through FIG. 17. Herein, a description will be given of a method for manufacturing a circuit device when the first conductive pattern 11 has a monolayer wiring structure. Steps other than the step for forming the first conductive pattern 11 are the same when the first conductive pattern 11 has a multilayer wiring structure.

First step: see FIG. 5 through FIG. 7.

This step is for forming a first conductive pattern 11. Herein, a description will be given of a method for forming a first conductive pattern 11 having a monolayer wiring structure. Accordingly, this step is for preparing a conductive foil 30 and forming a plurality of first conductive patterns 11 by forming, in the conductive foil 30, separating grooves 32 shallower than the thickness thereof.

In this step, first, as in FIG. 5, a sheet-like conductive foil 30 is prepared. Material for this conductive foil 30 is selected with brazing material's adhering characteristics, bonding characteristics, and plating characteristics taken into consideration, and as a material, a conductive foil made of Cu as a main material, a conductive foil made of Al as a main material, or a conductive foil made of an alloy such as Fe—Ni is employed.

The thickness of the conductive foil is preferably 10 μm-300 μm when subsequent etching is taken into consideration, however, basically, even 300 μm or more or 10 μm or less is satisfactory. As will be described later, it is sufficient that separating grooves 32 shallower than the thickness of the conductive foil 30 can be formed. Moreover, the sheet-like conductive foil 30 is prepared with a roll form wound with a predetermined width of, for example, 45 mm, and this may be transferred to respective steps to be described later, or strip-like conductive foil 30 cut to a predetermined size may be prepared and transferred to respective steps to be described later. Subsequently, a conductive pattern is formed.

First, as shown in FIG. 6, a photoresist (etching-resist mask) 3 is formed on the conductive foil 30, and the photoresist PR is patterned so that the conductive foil 30 except for regions to be a first conductive pattern 11 is exposed.

Then, referring to FIG. 7, the conductive foil 30 is selectively etched. Herein, as the first conductive pattern 11, a first conductive pattern 11A to form a die pad and first conductive patterns 11B to form bonding pads are provided.

Second step: see FIG. 8.

This step is for fixing a first circuit element 12 to the first conductive pattern 11.

Referring to FIG. 8, a first circuit element 12 is mounted on the first conductive pattern 11A via a brazing material. Herein, as the brazing material, a conductive paste such as solder or an Ag paste is used. Furthermore, wire bonding between the electrodes of the first circuit element 12 and desirable first conductive patterns 11B is carried out. Concretely, the electrodes of the first circuit element 12 mounted on the first conductive pattern 11A and desirable first conductive pattern 11B are wire-bonded in a lump by ball bonding by thermocompression and by wedge bonding by ultrasonic waves.

Herein, one IC chip is, as a first circuit element 12, fixed to the first conductive pattern 11A, however, an element other than the IC chip may also be employed as a first circuit element 12. Concretely, as the first circuit element 12, in addition to an IC chip, an active element such as a transistor chip or a diode and a passive element such as a chip resistor or a chip capacitor can be employed. Still furthermore, a plurality of elements of these active elements and passive elements can also be arranged on the first conductive pattern 11.

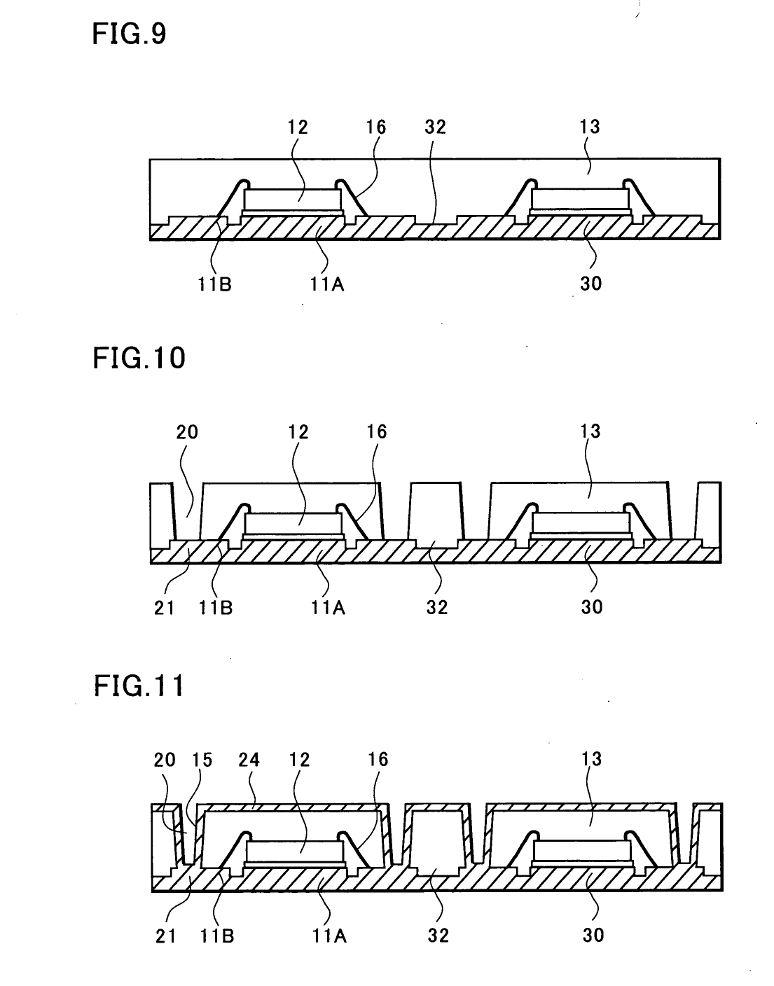

Third step: see FIG. 9.

This step is for molding with an insulating resin 13 so as to cover at least the first circuit element 12. Concretely, this step is for molding with an insulating resin 13 so as to cover the first circuit element 12 and to be filled into the separating grooves 32.

In this step, as shown in FIG. 9, the insulating resin 13 covers a first circuit element 12 and a plurality of conductive patterns 11, and the insulating resin 13 is filled into the separating grooves 32 and firmly latched with the separating grooves 32. Then, the first conductive patterns 11 are supported by the insulating resin 13. In addition, this step can be realized by transfer molding, injection molding, or potting. As the resin material, a thermosetting resin such as an epoxy resin can be realized by transfer molding, and a thermoplastic resin such as a polyimide resin or polyphenylene sulfide can be realized by injection molding.

An advantage of the preferred embodiment exists in that the conductive foil 30 to be the first conductive pattern 11 serves as a support substrate until it is covered with the insulating resin 13. Priorly, a conductive pattern has been formed by employing an unnecessary support substrate, however, in the preferred embodiment, the conductive foil 30 to be a support substrate is necessary as an electrode material. Therefore, an advantage exists in that operation is possible with the least possible number of component materials, and a reduction in cost can also be realized. In addition, since the separating grooves 32 have been formed shallower than the thickness of the conductive foil, the conductive foil 30 is not separated into individual first conductive patterns 11. Accordingly, this can be integrally handled as a sheet-like conductive foil 30, and during molding with the insulating resin 13, operations for transferring the same to a metal cast and mounting the same on the metal cast become considerably easy.

Fourth step: see FIG. 10.

This step is for forming throughholes 20 in the insulating resin 13 so that the first conductive pattern 11 is exposed.

In this step, the upper surface of the first conductive pattern 11B is exposed by forming the throughholes 20 by partial removal of the insulating resin 13. Concretely, the through holes 20 are formed by removing a part of the insulating resin 13 by a laser, whereby the exposed portions 21 are exposed. Herein, as the laser, a carbon oxide laser is preferable. In addition, if a residue remains at the exposed portions 21 after the insulating resin 13 is vaporized by the laser, this residue is removed by wet etching with sodium permanganate or ammonium persulfate.

A planar shape of the through hole 20 to be formed by the laser is a circular shape. In addition, a planar size of a section of a through hole 20 is formed to be smaller as it is closer to the bottom portion of the through hole 20.

Fifth step: FIG. 11 through FIG. 14.

This step is for forming a second conductive pattern 14 on an upper surface of the insulating resin 13 and, furthermore, forming connection means 15 on a side surface and a bottom surface of said through holes 20.

Referring to FIG. 11, in this step, a plated film made of a metal such as copper is formed by electrolytic plating or electroless plating on the upper surface of the insulating resin 13, side surface portions of the through holes 20, and exposed portions 21, thus the second conductive pattern 14 and connections means 15 are formed. In the case that a plated film is formed by electrolytic plating, the rear surface of the conductive foil 30 is used as an electrode. In FIG. 11, a plated film having a thickness equivalent to that of a conductive film 24 is formed on the side surface portions of the through holes 20 and exposed portions 21, as well, however, it is also possible to fill the through holes 20 with a plating material. When the through holes 20 are filled with a metal, a plating solution to which an additive has been added is used, and such plating is generally called filling plating.

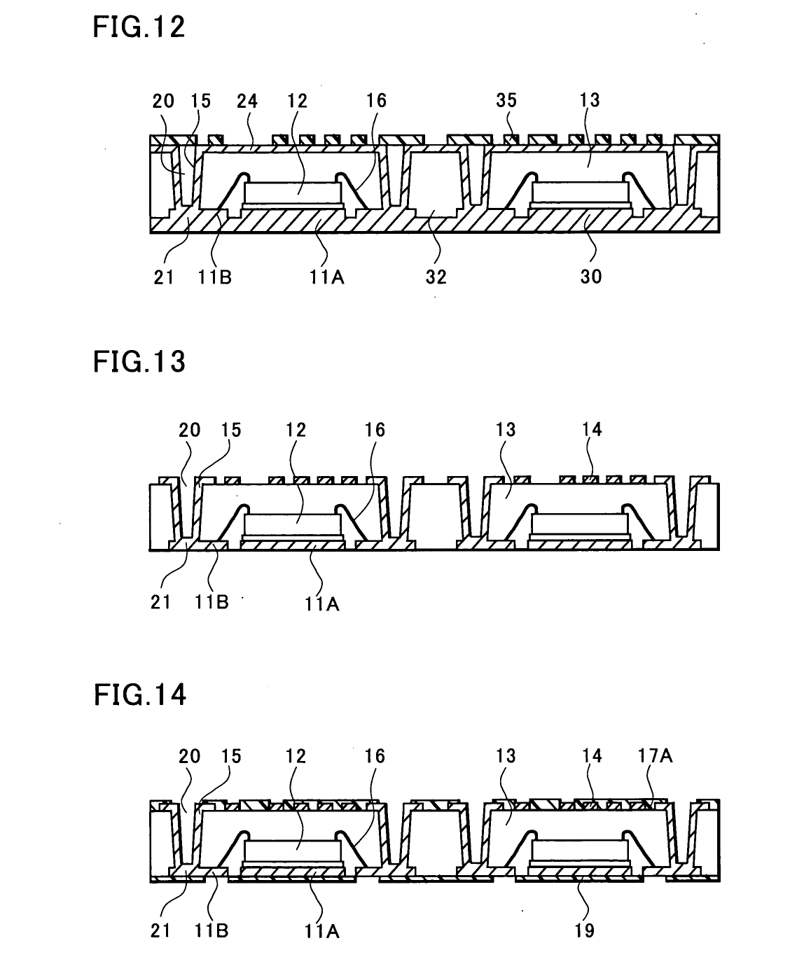

Next, referring to FIG. 12, a resist 35 is formed so that a desirable second conductive pattern 14 is formed on an upper surface of the conductive film 24, which is formed on the upper surface of the insulating resin 13.

Next, referring to FIG. 13, the second conductive pattern 14 is formed by selectively etching the conductive film 24 while using the resist 35 as a mask. Furthermore, herein, the conductive film 24 at positions corresponding to boundary between a plurality of respective circuit devices formed in a matrix form is also removed. In addition, after etching is finished, the resist 35 is peeled. Still furthermore, in this step, simultaneously with forming the conductive film 24 by etching, a shielding layer may be formed. In this case, the shield layer is formed on the upper surface of the insulating resin 13, at a remaining part where the second conductive pattern 14 is not formed. Moreover, the shield layer maybe electrically connected to the first conductive pattern 11B via connection means 15.

Still furthermore, by entirely removing the rear surface of the conductive foil 30 without masking, the respective first conductive patterns 11 are electrically separated. Concretely, the rear surface of the conductive foil 30 is chemically and/or physically removed, whereby the first conductive pattern 11 is separated. This step is carried out by polishing, grinding, etching, or metal vaporization by a laser. In the experiment, the conductive foil 30 is entirely wet-etched to expose the insulating resin 13 from the separating groove 32. As a result, the first conductive pattern 11 is separated to be a first conductive pattern 11A and first conductive patterns 11B, and the rear surface of the first conductive pattern 11 is exposed to the insulating resin 13.

Next, referring to FIG. 14, openings are formed at positions where external electrodes 18 are to be formed, and a solder resist 19 is applied on the rear surface of the insulating resin 13. These openings 33 are formed by exposure and development.

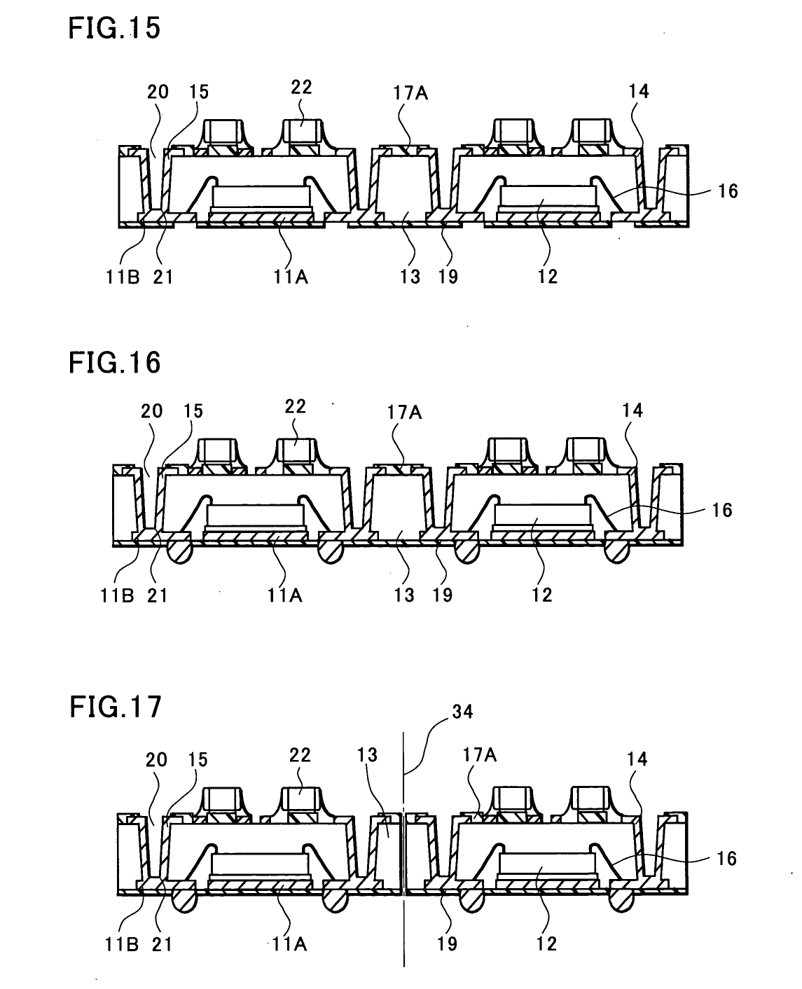

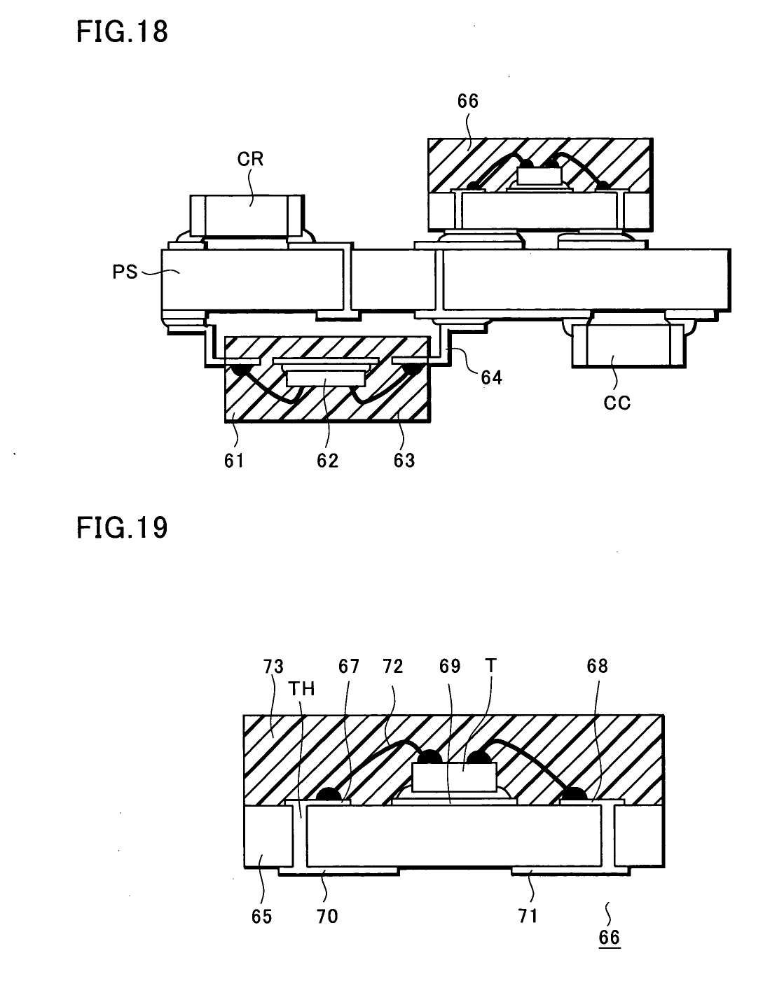

Sixth step: see FIG. 15 and FIG. 16.

This step is for mounting second circuit elements 22 on the second conductive pattern 14. Referring to FIG. 15, second circuit elements 22 are fixed via a brazing material such as solder onto the second conductive pattern 14 formed on the upper surface of the insulating resin 13. As the second circuit elements 22, passive components such as chip resistors or chip capacitors can be employed. Furthermore, semiconductor elements such as ISIs can also be employed.

Next, referring to FIG. 16, external electrodes 18 are formed on the rear surface of the first conductive pattern 11B exposed through the openings of the solder resist 19. Concretely, by applying a brazing material such as solder to the openings 33 by screen printing, and fusing the same, external electrodes 18 are formed.

Seventh step: see FIG. 17.

This step is for separating into respective circuit devices by dicing the insulating resin 13.

In this step, by dicing the insulating resin 13 at positions corresponding to the boundary between the respective circuit devices 10, the circuit devices are separated. The conductive foil 30 at positions corresponding to dicing lines 34 has been removed through the step for etching the conductive foil from its rear surface. In addition, the second conductive pattern 14 at positions corresponding to the dicing lines 34 has also been removed by etching. Accordingly, in this step, since a blade for dicing cuts and removes only the insulating resin 13, wearing of the blade can be suppressed to a minimum.

Through the above steps, the circuit device 10 is manufactured, and the final shape as shown in FIG. 1 or FIG. 2 can be obtained.

An advantage of the preferred embodiment exists in that the second conductive pattern 14 provided on the upper surface of the insulating resin 13 and the connection means 15 are formed simultaneously. Concretely, the second conductive pattern 14 and connection means 15 are an integrated plated film, which is formed by electrolytic plating or electroless plating. Accordingly, an increase in the number of process steps as a result of forming the shield layer 14 can be suppressed as much as possible.

Furthermore, an advantage of the preferred embodiment exists in that the through holes 20 are formed in the insulating resin 13 by use of a laser. Concretely, since only the insulating resin 13 can be removed by adjusting the output of the laser, removal by laser can be stopped at the interface between the insulating resin 13 and first conductive pattern 11.

Herein, in the above description, the through holes 20 have been formed by use of a laser, however, it is also possible to form through holes 20 by methods other than the method using a laser. Concretely, in the step for molding with the insulating resin 13, convex parts corresponding to the shape of the through holes 20 are provided for the mold die which is brought into contact with the upper surface of the insulating resin 13. Then, by carrying out sealing with the insulating resin 13 while bringing the front-end parts of the convex parts into contact with the upper surface of the conductive pattern, through holes 20 of a shape corresponding to the shape of these convex parts can be formed.

In addition, in the above description, the connection means 15 have been formed by plating along with the second conductive pattern 14, however, it is also possible to form the connection means 14 of a conductive paste such as an Ag paste. Furthermore, it is also possible to form both the connection means 15 and second conductive pattern 14 of a conductive paste.

What is claimed is:

1. A circuit device comprising:
a first conductive pattern;
a first circuit element mounted on the first conductive pattern;
an insulating resin for covering at least the first circuit element and the first conductive pattern;
a second conductive pattern provided on an upper surface of the insulating resin;
a through hole formed in the insulating resin so that an upper surface of the first conductive pattern is partially exposed;
a connection means provided on a bottom surface and a side surface of the through hole and electrically connecting the first conductive pattern with the second conductive pattern; and
a second circuit element mounted on the second conductive pattern.

2. The device of claim 1, wherein
the first conductive pattern has a monolayer wiring structure, and a rear surface of the first conductive pattern is exposed from the insulating resin.

3. The device of claim 1, wherein
the first conductive pattern and the second conductive pattern are formed of a metal such as copper.

4. The device of claim 1, wherein
the second conductive pattern and the connection means are integrally formed of an identical material.

5. The device of claim 1, wherein
the second conductive pattern and the connection means are formed of a plated film.

6. The device of claim 1, wherein
the second circuit element is a chip resistor or a chip capacitor.

7. The device of claim 1, wherein
a shield layer is provided on an upper surface of the insulating resin, at a region except where the second conductive pattern is provided.

8. The device of claim 7, wherein
the shield layer and the first conductive pattern are electrically connected via the connection means.

9. A method for manufacturing a circuit device comprising the steps of:
forming a first conductive pattern;
fixing a first circuit device to the first conductive pattern;
molding with an insulating resin so as to cover at least the first circuit element;
forming through holes in the insulating resin so that the first conductive pattern is exposed;
forming a second conductive pattern on an upper surface of the insulating resin and, furthermore, forming connection means on a side surface and a bottom surface of the through holes;
mounting a second circuit element on the second conductive pattern; and
separating into respective circuit devices by dicing the insulating resin.

10. The method of claim 9, wherein
the through holes are formed by use of a laser.

11. The method of claim 9, wherein
the second conductive pattern and the connection means are formed by a plating method.

12. The method of claim 9, wherein
the monolayer first conductive pattern is formed by forming separating grooves in a conductive foil, the insulating resin is filled into the separating grooves, and respective first conductive patterns are electrically isolated by removing a rear surface of the conductive foil until the insulating resin is exposed.
